(19) United States
(12) Patent Application Publication
(10) Pub. No.: US 2006/0273298 A1
(43) Pub. Date: Dec. 7, 2006

(54) Rewriteable memory cell comprising a transistor and resistance-switching material in series

(75) Inventor: Christopher J. Petti, Mountain View, CA (US)

Correspondence Address: MATRIX SEMICONDUCTOR, INC., 3230 SCOTT BOULEVARD, SANTA CLARA, CA, 95054, US

(73) Assignee: Matrix Semiconductor, Inc., Santa Clara, CA (US)

(21) Appl. No.: 11/143,269

(22) Filed: Jun. 2, 2005

(51) Int. Cl. H01L 29/06

(52) U.S. Cl. 257/5

(57) ABSTRACT

A nonvolatile memory cell is provided, the cell comprising a transistor in series with resistance-switching material, which can be switched between at least two stable resistance states, for example a high-resistance state and a low-resistance state. In preferred embodiments the transistor is a TFT, having a channel region not formed in a monocrystalline wafer substrate. In preferred embodiments the transistor may have either a vertically oriented channel or a laterally oriented channel. Either embodiment can be formed in a monolithic three dimensional memory array in which multiple memory levels can be formed above a single substrate, forming a highly dense nonvolatile memory array.

### BACKGROUND OF THE INVENTION

The invention relates to a nonvolatile memory cell comprising a reversible resistance-switching memory element.

Resistance-switching materials, which can reversibly be converted between a high-resistance state and a low-resistance state, are known. These two stable resistance states make such materials an attractive option for use in a rewriteable non-volatile memory array. It is very difficult to form a large, high-density array of such cells, however, due to the danger of disturbance between cells, high leakage currents, and the difficulty of providing precisely controlled read, set, and reset voltages to the resistance-switching material.

There is a need, therefore, for a nonvolatile memory cell having a reversible resistance-switching memory element which can readily be adapted for use in a large, highly dense monolithic three dimensional memory array.

### SUMMARY OF THE PREFERRED EMBODIMENTS

The present invention is defined by the following claims, and nothing in this section should be taken as a limitation on those claims. In general, the invention is directed to a nonvolatile memory cell comprising a reversible resistance-switching memory element in series with a transistor. Large monolithic three dimensional memory arrays can be formed using such a memory cell.

A first aspect of the invention provides for a nonvolatile memory cell comprising: a reversible resistance-switching binary metal oxide or nitride element; and a transistor, the resistance-switching element and the transistor arranged in series.

Another aspect of the invention provides for a nonvolatile memory cell comprising: a reversible resistance-switching element, wherein resistance switching is not achieved through phase change; and a thin film transistor having a deposited semiconductor channel region, wherein the thin film transistor and the resistance-switching element are arranged in series.

Yet another aspect of the invention provides for a nonvolatile memory cell comprising: a vertically oriented transistor having a polycrystalline channel region; and a reversible resistance-switching element, wherein resistance switching is not achieved through phase change, wherein the resistance-switching element is electrically in series with the vertically oriented transistor.

A preferred embodiment of the invention provides for a monolithic three dimensional memory array comprising: a) a first memory level formed above a substrate, the first memory level comprising a first plurality of memory cells, each first memory cell comprising: i) a transistor; and ii) a reversible resistance-switching element, wherein resistance switching is not achieved through phase change, the transistor and the resistance-switching element arranged in series; and b) a second memory level monolithically formed above the first memory level.

Another preferred embodiment of the invention provides for a method for forming a monolithic three dimensional memory array, the method comprising: forming a first plurality of substantially parallel, substantially coplanar data lines above a substrate; forming a first plurality of vertically oriented transistors above the first data lines; forming a first plurality of reversible resistance-switching elements; and forming a first plurality of substantially parallel, substantially coplanar reference lines above the first transistors, wherein one of the first resistance-switching elements and one of the first transistors is arranged in series between each of the first data lines and each of the first reference lines.

Yet another preferred embodiment provides for a monolithic three dimensional memory array comprising: a) a first plurality of substantially parallel, substantially coplanar rails extending in a first direction, wherein some of the first rails are first data lines and others of the first rails are first reference lines; b) a first plurality of substantially parallel, substantially coplanar select lines above the first rails extending in a second direction different from the first direction; c) a first plurality of pillars, each pillar disposed between one of the first rails and one of the first select lines; and d) a plurality of first memory cells, wherein each first memory cell comprises: one of the first pillars comprising a reversible resistance-switching memory element; one of the first pillars not comprising a reversible resistance-switching memory element; and a semiconductor channel region.

Each of the aspects and embodiments of the invention described herein can be used alone or in combination with one another.

The preferred aspects and embodiments will now be described with reference to the attached drawings.

### BRIEF DESCRIPTION OF THE DRAWINGS

FIG. 1 is a perspective view of a possible memory cell having a resistance-switching material disposed between conductors.

FIGS. 2a-2c are alternate views of a preferred embodiment of the present invention. FIGS. 2a and 2c are cross-sectional views, while FIG. 2b is a plan view.

FIG. 3 is a cross-sectional view of a different preferred embodiment of the present invention.

FIGS. 4a-4j are views showing stages in formation of a first embodiment of the present invention. FIGS. 4c and 4j are plan views; the rest are cross-sectional views.

FIG. 5 is a cross-sectional view showing two memory levels according to the embodiment of FIGS. 4a-4j sharing reference lines.

FIG. 6a is a cross-sectional view showing four memory levels according to the embodiment of FIGS. 4a-4j sharing reference lines and data lines. FIG. 6b is a cross-sectional view showing four memory levels according to the embodiment of FIGS. 4a-4j sharing reference lines, but not sharing data lines.

FIGS. 7a-7c are circuit diagrams describing voltages applied to set, reset, and read a selected memory cell S in an array formed according to the first embodiment of the present invention.

FIGS. 8a-8g are cross-sectional views showing stages in formation of a second embodiment of the present invention.

FIGS. 9a-9c are circuit diagrams describing voltages applied to set, reset, and read a selected memory cell S in an array formed according to the second embodiment of the present invention.

### DETAILED DESCRIPTION OF THE PREFERRED EMBODIMENTS

A variety of materials show reversible resistance-switching behavior. These materials include chalcogenides, carbon polymers, perovskites, and certain metal oxides and nitrides. Specifically, there are metal oxides and nitrides which include only one metal and exhibit reliable resistance switching behavior. This group includes, for example, NiO, Nb₂O₅, TiO₂, HfO₂, Al₂O₃, MgOₓ, CrO₂, VO, BN, and AlN, as described by Pagnia and Sotnick in “Bistable Switching in Electroformed Metal-Insulator-Metal Device,” Phys. Stat. Sol. (A) 108, 11-65 (1988). Such materials include two elements, a single metal and oxygen or nitrogen in a binary compound. Terms such as binary metal oxide or nitride resistance-switching material and resistance-switching binary metal oxide or nitride will refer to such material.

The change in resistance exhibited by chalcogenides is due to a temperature-induced change in phase. Generally the high-resistance state of a chalcogenide is an amorphous state, while the low-resistance state is more highly crystalline. The conversion is caused by melting and recrystallizing the material under appropriate conditions. Many chalcogenide-based memory cells are adapted to concentrate heat in the area of a chalcogenide layer to be converted to affect this phase change. In contrast, the resistance-switching behavior of the binary metal oxides and nitrides is not achieved through phase change. Voltage or current, rather than high temperature, induces the reversible resistance switch.

A layer of one of these materials may be formed in an initial state, for example a relatively low-resistance state. Upon application of sufficient voltage or current, the material switches to a stable high-resistance state. This resistance switching is reversible; subsequent application of appropriate current or voltage can serve to return the resistance-switching material to a stable low-resistance state. This conversion can be repeated many times. For some materials, the initial state is high-resistance rather than low-resistance. When this discussion refers to “resistance-switching material”, “resistance-switching binary metal oxide or nitride”, “resistance-switching memory element” or similar terms, it will be understood that a reversible resistance-switching material is meant.

These reversible resistance-switching materials are thus of interest for use in nonvolatile memory arrays. One resistance state may correspond to a data “0”, for example, while the other resistance state corresponds to a data “1”. Some of these materials may have more than two stable resistance states.

To make a memory cell using these materials, the difference in resistivity between the high-resistivity state and the low-resistivity state must be large enough to be readily detectable. For example, the resistivity of the material in the high-resistivity state should be at least three times that of the material in the low-resistivity state. When this discussion refers to “resistance-switching material”, “resistance-switching metal oxide or nitride”, “resistance-switching memory element” or similar terms, it will be understood that the difference between the low- and high-resistance or low- or high-resistivity states is at least a factor of three.

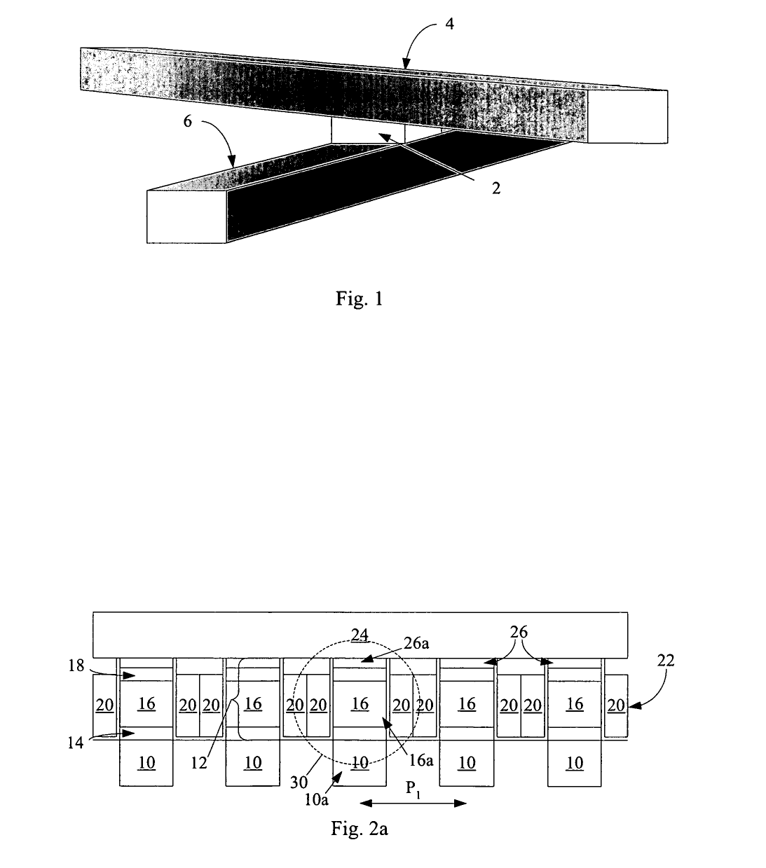

Many obstacles exist to using these resistance-switching materials in a large nonvolatile memory array, however. In one possible arrangement a plurality of memory cells are formed, each as shown in FIG. 1, comprising a resistance-switching memory element 2 (comprising one of the resistance-switching materials named), disposed between conductors, for example between a top conductor 4 and a bottom conductor 6, in a cross-point array. A resistance-switching memory element 2 is programmed by applying voltage between the top conductor 4 and bottom conductor 6.

In a large array of such cells arranged in a cross-point array, however, and when relatively large voltage or current is required, there is danger that memory cells that share the top or the bottom conductor with the cell to be addressed will be exposed to sufficient voltage or current to cause undesired resistance switching in those half-selected cells. Depending on the voltages applied, excessive leakage current across unselected cells may also be a concern.

The present invention describes a memory cell having a reversible resistance-switching memory element in series with a transistor. The transistor provides the set and reset voltages to convert the reversible resistance-switching element between its high-resistance and low-resistance states. When the memory cell is read, the reversible resistance-switching memory element behaves either as a resistor having high resistance or one having low resistance in series with the transistor, depending on its resistance state, and thus regulates the current that flows through the cell at given voltage conditions.

In preferred embodiments, the transistor is a thin film transistor (TFT), in which a channel region of the transistor is not formed in a monocrystalline semiconductor substrate. The channel region is instead formed in a deposited semiconductor material, which is preferably polycrystalline in the completed array. The channel region could be polycrystalline, amorphous, microcrystalline semiconductor material. Multiple memory levels of such memory cells can be formed stacked above a single monocrystalline silicon wafer substrate (or other appropriate substrate) to form a very dense monolithic three dimensional memory array.

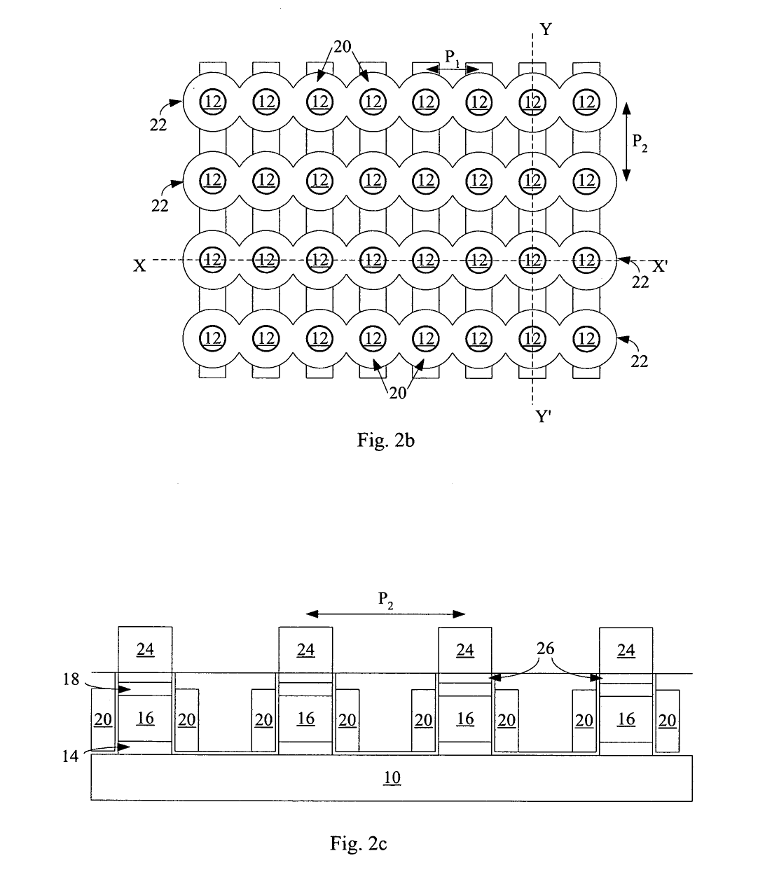

Two families of embodiments will be described. Turning to FIG. 2a, in the first, the transistor is oriented vertically. A plurality of substantially parallel data lines 10 is formed. Semiconductor pillars 12 are formed, each above one of the data lines 10. Each pillar 12 includes heavily doped regions 14 and 18 which serve as drain and source regions, and a lightly doped region 16 which serves as a channel region. A gate electrode 20 surrounds each pillar 12.

FIG. 2b shows the cells of FIG. 2a viewed from above. In a repeating pattern, pitch is the distance between a feature and the next occurrence of the same feature. For example, the pitch of pillars 12 is the distance between the center of one pillar and the center of the adjacent pillar. In one direction pillars 12 have a first pitch P₁, while in other direction, pillars 12 have a larger pitch P₂; for example P₂ may be 1.5 times larger than P₁. (Feature size is the width of the smallest feature or gap formed by photolithography in a device. Stated another way, pitch P₁ may be double the feature size, while pitch P₂ is three times the feature size.) In the direction having the smaller pitch P₁, shown in FIG. 2a, the gate electrodes 20 of adjacent memory cells merge, forming a single select line 22. In the direction having larger pitch P₂, gate electrodes 20 of adjacent cells do not merge, and adjacent select lines 22 are isolated. FIG. 2a shows the structure in cross-section along line X-X′ of FIG. 2b, while FIG. 2c shows the structure in cross-section along line Y-Y′ of FIG. 2b.

Referring to FIG. 2a and 2c, reference lines 24, preferably perpendicular to data lines 10, are formed above the pillars 12, such that each pillar 12 is vertically disposed between one of the data lines 10 and one of the reference lines 24. A resistance-switching memory element 26 is formed in each memory cell between source region 18 and reference line 24, for example. Alternatively, resistance-switching memory element can be formed between drain region 14 and data line 10. Resistance-switching memory elements 26 are preferably sandwiched between layers of a noble metal, for example Ir, Pt, Pd or Au (not shown.) Some binary metal oxide or nitride resistance switching materials have been shown to switch more reliably when in contact with such noble metals.

FIG. 2a shows a plurality of memory cells, each comprising a source region 18, a channel region 16, and a drain region 14, a gate electrode 20, a resistance-switching memory element 26, which is accessed by one of select lines 22, data lines 10, and reference lines 24. The cell comprises a vertically oriented pillar 12, which comprises channel region 16. Referring to FIG. 2a, suppose resistance-switching element 26a of memory cell 30 is in a low-resistance state. When a voltage above threshold voltage is applied to select line 22, a conductive channel forms in the transistor channel regions 16a along select line 22. With appropriate read voltages applied between data line 10a and reference line 24, an appreciable current flows, because low-resistance resistance-switching element 26a conducts it.

Suppose a sufficient current is then applied to resistance-switching memory element 26a to convert it to a high-resistance state. When read voltages are again applied to the select line 22, data line 10a, and reference line 24, the resistance-switching element 26a, now in a high-resistance state, will act as a resistor and significantly less current will flow. In this way cell 30 can store a memory state, acting as a memory cell.

Each memory cell of this embodiment has a vertically oriented transistor having a polycrystalline channel region and a reversible resistance-switching element, the two electrically in series.

Many aspect of the memory array shown in FIGS. 2a-2c can be varied. Data lines 10 can be formed above reference lines 24, for example, and drain regions 14 can be above source regions 18, or resistance switching elements 26 can be below rather than above semiconductor pillars 12. It will be apparent to those skilled in the art that these and other variations fall within the scope of the invention.

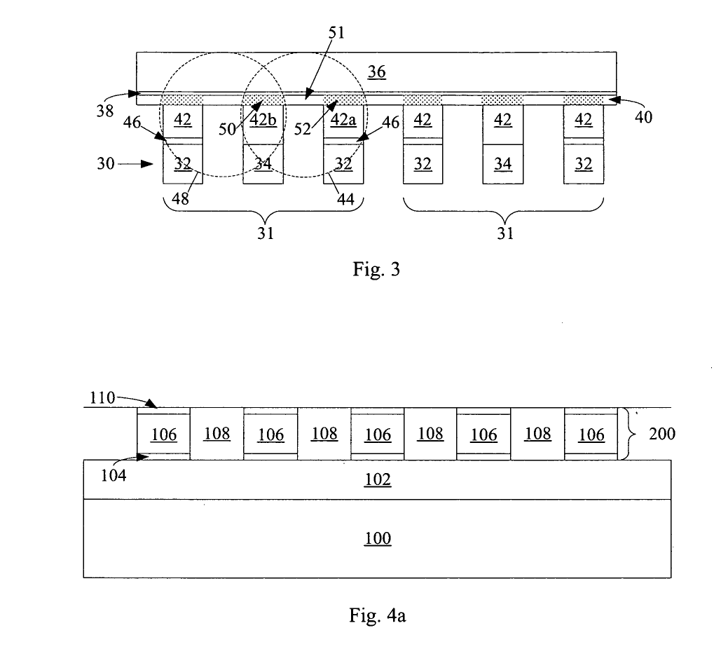

Turning to FIG. 3, the second embodiment similarly includes memory cells in a TFT array, each having a transistor and a reversible resistance-switching memory element in series, but has a different structure. Substantially parallel rails 30 (shown in cross section, extending out of the page) include a plurality of line sets 31, each line set 31 consisting of two data lines 32 and one reference line 34, reference line 34 immediately adjacent to and between the two data lines 32. Above the rails 30 and preferably extending perpendicular to them, are substantially parallel select lines 36. Select lines 36 are coextensive with gate dielectric layer 38 and channel layer 40. The memory level includes pillars 42, each pillar 42 vertically disposed between one of the channel layers 40 and one of the data lines 32 or one of the reference lines 34. Transistors are formed comprising adjacent pillars along the same select line. Transistor 44 includes channel region 51 between source region 50 and drain region 52. One pillar 42a includes resistance-switching element 46, while the other pillar 42b does not. In this embodiment, adjacent transistors share a reference line; for example transistor 48 shares a reference line 34 with transistor 44. No transistor exists between adjacent data lines 32.

In the embodiment of FIGS. 2a-2c, the channel region is substantially vertical. In the embodiment of FIG. 3, the channel region is substantially horizontal.

This embodiment can similarly be varied in many ways while falling within the scope of the invention.

Lee et al., U.S. Pat. No. 6,881,994, “Monolithic Three Dimensional Array of Charge Storage Devices Containing a Planarized Surface”; and Walker et al., U.S. patent application Ser. No. 10/335,089, “Method for Fabricating Programmable Memory Array Structures Incorporating Series-Connected Transistor Strings,” filed Dec. 31, 2002, assigned to the assignee of the present invention and hereby incorporated by reference, describe monolithic three dimensional memory arrays in which the memory cells comprise transistors.

Herner et al., U.S. application Ser. No. 10/326,470, “An Improved Method for Making High Density Nonvolatile Memory,” filed Dec. 19, 2002, since abandoned, hereinafter the '470 application, describes fabrication and operation of a monolithic three dimensional memory array comprising vertically oriented semiconductor diodes disposed between conductors. Herner et al., U.S. application Ser. No. 11/125,939, “Rewriteable Memory Cell Comprising a Diode and a Resistance-Switching Material,” filed May 9, 2005, hereinafter the '939 application, describes fabrication and operation of a monolithic three dimensional array comprising vertically oriented diodes, each formed in series with a reversible resistance-switching memory element. Herner et al., U.S. application Ser. No. 11/125,606, “High-Density Nonvolatile Memory Array Fabricated at Low Temperature Comprising Semiconductor Diodes,” filed May 9, 2005, hereinafter the '606 application, describes low temperature fabrication techniques for use with such arrays. The '470, '939, and '606 applications are owned by the assignee of the present invention and are hereby incorporated by reference.

Detailed examples will be provided, one describing fabrication of a monolithic three dimensional memory array formed according to the embodiment of FIGS. 2a-2c, and another describing fabrication of a monolithic three dimensional memory array formed according to the embodiment of FIG. 3. Fabrication techniques described in Lee et al., in Walker et al., and in the '470, '939, and '606 applications will prove useful during fabrication of memory arrays according to the present invention. For simplicity, not all fabrication details from those applications will be included in the descriptions herein, but it will be understood that no teaching of these incorporated patents and applications is intended to be excluded.

For clarity many details, including steps, materials, and process conditions, will be included. It will be understood that this example is non-limiting, and that these details can be modified, omitted, or augmented while the results fall within the scope of the invention.

Vertical Transistor Embodiment: Fabrication

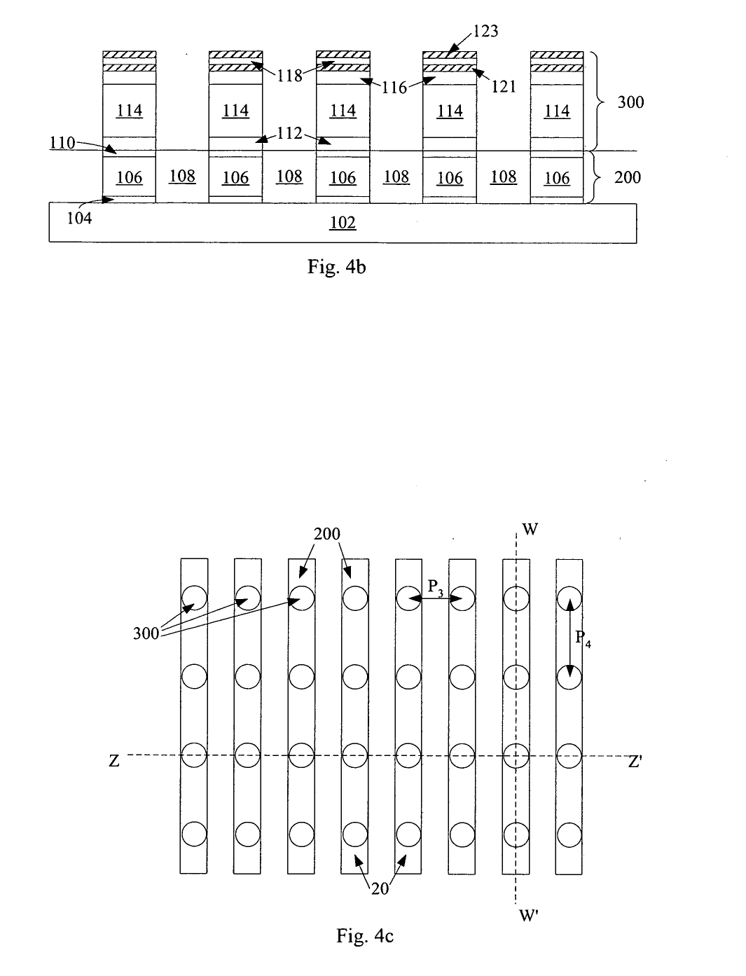

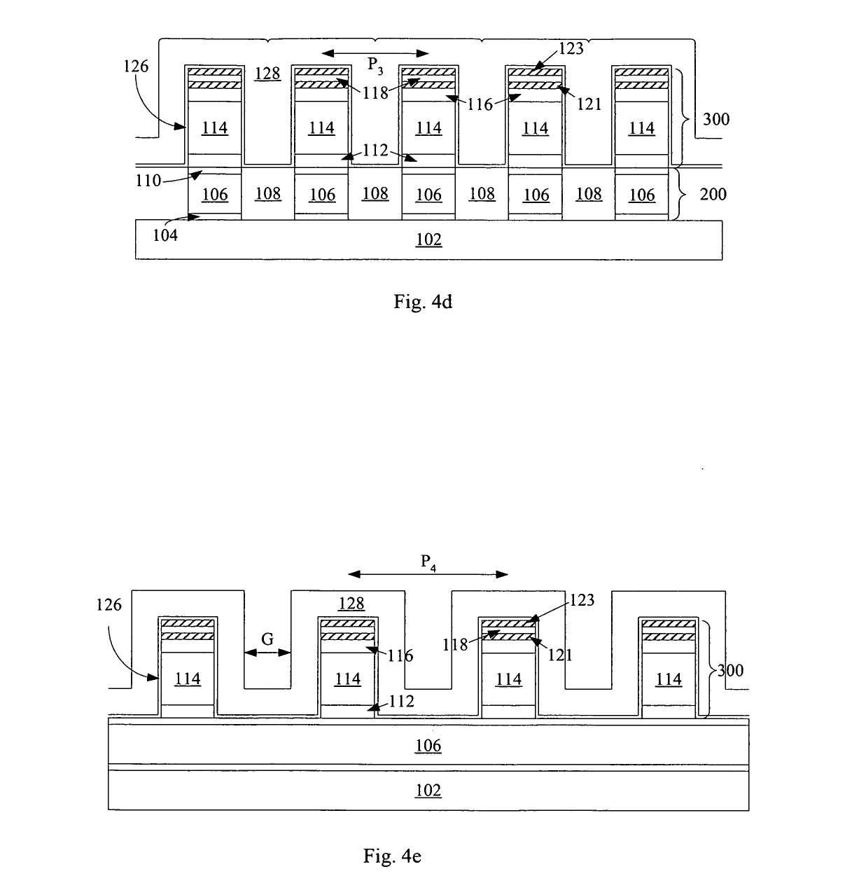

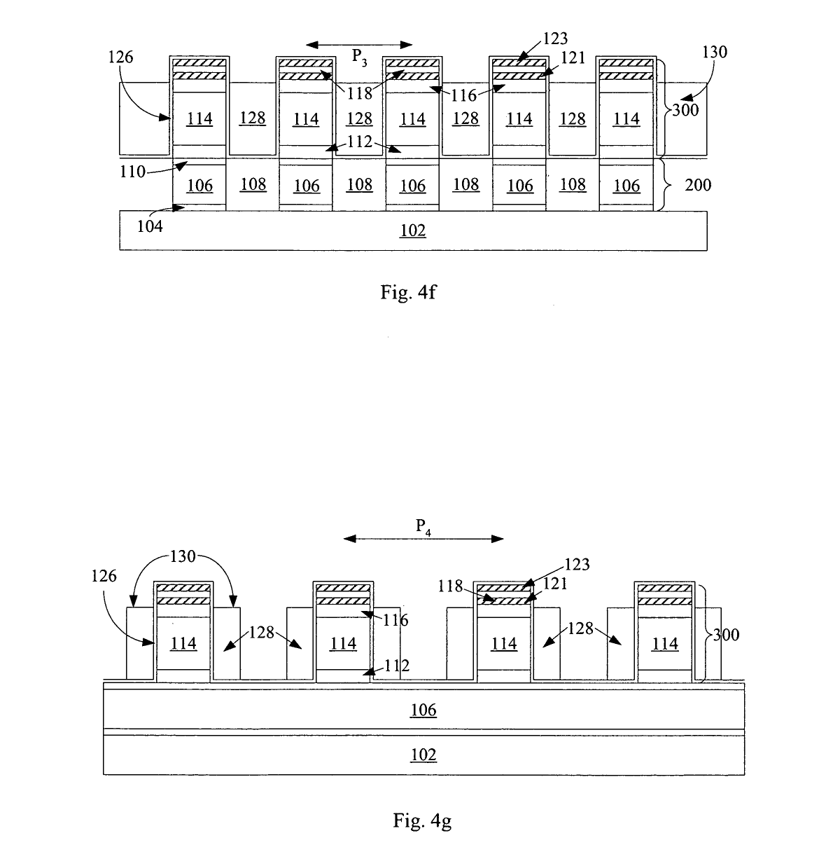

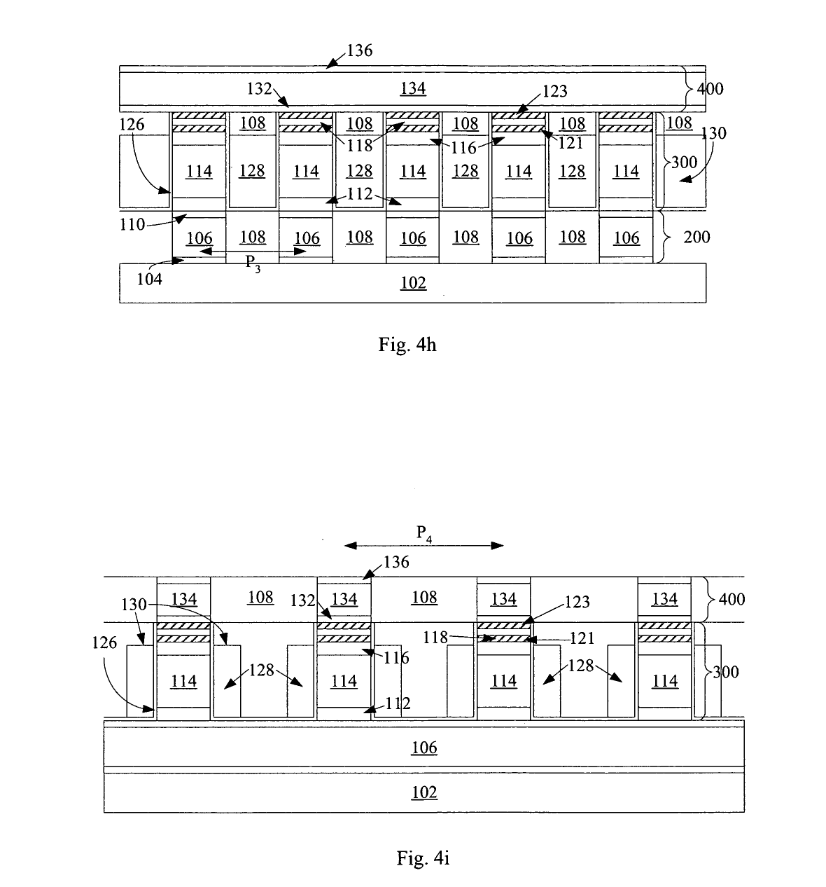

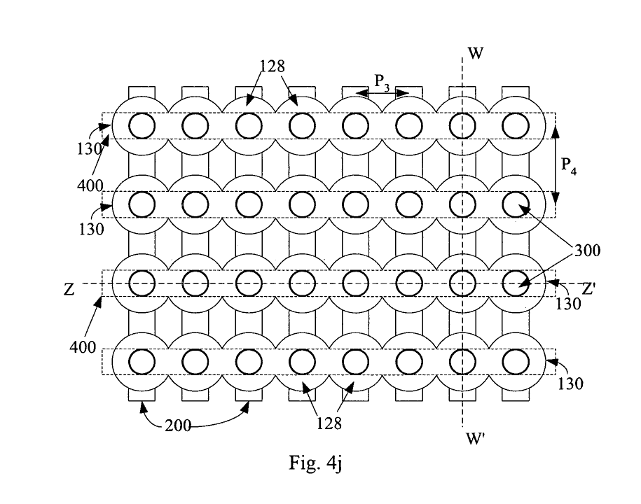

Turning to FIG. 4a, formation of the memory begins with a substrate 100. This substrate 100 can be any semiconducting substrate as known in the art, such as monocrystalline silicon, IV-IV compounds like silicon-germanium or silicon-germanium-carbon, III-V compounds, II-VII compounds, epitaxial layers over such substrates, or any other semiconducting material. The substrate may include integrated circuits fabricated therein.

An insulating layer 102 is formed over substrate 100. The insulating layer 102 can be silicon oxide, silicon nitride, high-dielectric film, Si—C—O—H film, or any other suitable insulating material.

Data lines 200 are formed over the substrate 100 and insulator 102. An adhesion layer 104 may be included between the insulating layer 102 and the conducting layer 106 to help the conducting layer 106 adhere. A preferred material for the adhesion layer 104 is titanium nitride, though other materials may be used, or this layer may be omitted. Adhesion layer 104 can be deposited by any conventional method, for example by sputtering.

The thickness of adhesion layer 104 can range from about 20 to about 500 angstroms, and is preferably between about 100 and about 400 angstroms, most preferably about 200 angstroms. Note that in this discussion, “thickness” will denote vertical thickness, measured in a direction perpendicular to substrate 100.

The next layer to be deposited is conducting layer 106. Conducting layer 106 can comprise any conducting material known in the art, such as doped semiconductor material, metals such as tungsten, or conductive metal silicides; in a preferred embodiment, conducting layer 106 is aluminum. The thickness of conducting layer 106 can depend, in part, on the desired sheet resistance and therefore can be any thickness that provides the desired sheet resistance. In one embodiment, the thickness of conducting layer 106 can range from about 500 to about 3000 angstroms, preferably between about 1000 and about 2000 angstroms, most preferably about 1200 angstroms.

Another layer 110, preferably of titanium nitride, is deposited on conducting layer 106. It may have thickness comparable to that of layer 104.

Once all the layers that will form the conductor rails have been deposited, the layers will be patterned and etched using any suitable masking and etching process to form substantially parallel, substantially coplanar data lines 200, shown in FIG. 4a in cross-section. In one embodiment, photoresist is deposited, patterned by photolithography and the layers etched, and then the photoresist removed, using standard process techniques such as “ashing” in an oxygen-containing plasma, and strip of remaining polymers formed during etch in a conventional liquid solvent such as those formulated by EKC.

Next a dielectric material 108 is deposited over and between data lines 200. Dielectric material 108 can be any known electrically insulating material, such as silicon oxide, silicon nitride, or silicon oxynitride. In a preferred embodiment, silicon oxide is used as dielectric material 108. The silicon oxide can be deposited using any known process, such as chemical vapor deposition (CVD), or, for example, high-density plasma CVD (HDPCVD).

Finally, excess dielectric material 108 on top of data lines 200 is removed, exposing the tops of data lines 200 separated by dielectric material 108, and leaving a substantially planar surface. The resulting structure is shown in FIG. 4a. This removal of dielectric overfill to form the planar surface can be performed by any process known in the art, such as etchback or chemical mechanical polishing (CMP). For example, the etchback techniques described in Raghuram et al., U.S. application Ser. No. 10/883417, “Nonselective Unpatterned Etchback to Expose Buried Patterned Features,” filed Jun. 30, 2004 and hereby incorporated by reference in its entirety, can advantageously be used.

In alternative embodiments, data lines 200 can be formed by a damascene method, for example comprising copper.

The width of data lines 200 can be as desired. In preferred embodiments, data lines 200 can have a width between about 45 and about 360 nm, preferably between about 90 and about 180 nm. In preferred embodiments, the gaps between data lines 200 have about the same width as data lines 200, though it may be greater or less. In preferred embodiments, the pitch of data lines 200 is between about 90 nm and about 720 nm, preferably between about 180 nm and about 360 nm.

Next, turning to FIG. 4b, vertical pillars will be formed above completed data lines 200. (To save space substrate 100 is omitted in FIG. 4b and subsequent figures; its presence should be assumed.) Semiconductor material that will be patterned into pillars is deposited. The semiconductor material can be germanium, silicon, silicon-germanium, silicon-germanium-carbon, or other suitable IV-IV compounds, gallium arsenide, indium phosphide, or other suitable III-V compounds, zinc selinide, or other II-VII compounds, or a combination. Silicon-germanium alloys of any proportion of silicon and germanium, for example including at least 20, at least 50, at least 80, or at least 90 atomic percent germanium or pure germanium may be used. The present example will describe the use of pure germanium. The term “pure germanium” does not exclude the presence of conductivity-enhancing dopants or contaminants normally found in a typical production environment.

In preferred embodiments, the semiconductor pillar comprises a bottom heavily doped region of a first conductivity type, a middle lightly doped region of a second conductivity type, and a top heavily doped region of the first conductivity type.

In this example, bottom heavily doped region 112 is heavily doped n-type germanium. In a most preferred embodiment, heavily doped region 112 is deposited and doped with an n-type dopant such as phosphorus by any conventional method, preferably by in situ doping, though alternatively through some other method, such as ion implantation. This layer is preferably between about 100 and about 800 angstroms, most preferably between about 200 and about 300 angstroms. Bottom heavily doped region 112 will behave as a source or drain region for the transistor to be formed.

Next the germanium that will form the remainder of the pillar, regions 114 and 116, is deposited. The lightly doped region 114 will preferably be between about 600 and about 2000 angstroms thick, preferably between about 900 and about 1500 angstroms thick. The top heavily doped region 116 should be between about 100 and about 500 angstroms thick, preferably between about 200 and about 300 angstroms thick. Thus between about 700 and about 2000 angstroms of germanium should be deposited to complete thickness required for the pillar. This germanium layer 114 is preferably lightly doped p-type germanium, and is preferably in-situ doped. The channel region of the transistor to be formed will be in germanium layer 114.

In some embodiments a subsequent planarization step will remove some germanium, so in this case an extra thickness is deposited. If the planarization step is performed using a conventional CMP method, about 800 angstroms of thickness may be lost (this is an average; the amount varies across the wafer. Depending on the slurry and methods used during CMP, the germanium loss may be more or less.) If the planarization step is performed by an etchback method, only about 400 angstroms of germanium or less may be removed.

In a preferred embodiment, top heavily doped n-type region 116 is preferably formed at this point by ion implantation. Heavily doped region 116, which will serve as a source/drain region for the transistor to be formed, is preferably between about 200 and about 300 angstroms thick.

Next a layer 121 of a conductive material, preferably a noble metal such as Ir, Pt, Pd or Au, is deposited. Other metals, conductive nitrides, or other conductive materials can be used for layer 121. The thickness of layer 121 may be between about 100 and about 400 angstroms, preferably about 200 angstroms. In some embodiments, layer 121 may be omitted, or some other conductive material can be used instead. A layer 118 of a binary metal oxide or nitride resistance-switching material is deposited on and in contact with conductive layer 121. This layer is preferably between about 200 and about 400 angstroms thick. Layer 118 can be any of the materials described earlier, and is preferably formed of a binary metal oxide or nitride having including exactly one metal which exhibits resistance switching behavior; preferably a material selected from the group consisting of NiO, Nb₂O₅, TiO₂, HfO₂, Al₂O₃, MgOₓ, CrO₂, VO, BN, and AlN. For simplicity this discussion will describe the use of NiO in layer 118. It will be understood, however, that any of the other materials described can be used.

Finally in preferred embodiments conductive layer 123 is deposited on and in contact with NiO layer 118. Layer 123 is preferably a noble metal such as Ir, Pt, Pd or Au, though some other appropriate conductive barrier material may be used instead. In some embodiments, layer 123 may be omitted.

Next a pattern and etch step is performed to etch pillars 300. Layers 123, 118, 121, 116, 114, and 112 are etched in this etch step.

The pillars 300 can be formed using any suitable masking and etching process. For example, photoresist can be deposited, patterned using standard photolithography techniques, and etched, then the photoresist removed. Alternatively, a hard mask of some other material, for example silicon dioxide, can be formed on top of the semiconductor layer stack, with bottom antireflective coating (BARC) on top, then patterned and etched. Similarly, dielectric antireflective coating (DARC) can be used as a hard mask.

After etch, pillars 300 include bottom heavily doped region n-type region 112, middle lightly doped p-type region 114, top heavily doped n-type region 116, conductive layer 121, NiO layer 118, and conductive layer 123. In some embodiments other layers, for example barrier layers, may be included.

The photolithography techniques described in Chen, U.S. application Ser. No. 10/728436, “Photomask Features with Interior Nonprinting Window Using Alternating Phase Shifting,” filed Dec. 5, 2003; or Chen, U.S. application Ser. No. 10/815312, Photomask Features with Chromeless Nonprinting Phase Shifting Window,” filed Apr. 1, 2004, both owned by the assignee of the present invention and hereby incorporated by reference, can advantageously be used to perform any photolithography step used in formation of a memory array according to the present invention.

The pillars 300 are preferably about the same width as data lines 200. Turning to FIG. 4c, which shows the structure viewed from above, it will be seen that pillars 300 have a first pitch P₃ in one direction and a second, larger pitch P₄ in the other direction. (Pillars 300 are pictured, in FIG. 4c, as substantially cylindrical. At small feature sizes, the photolithographic tends to round corners; thus independently patterned pillars will tend to be cylindrical.) The views of FIGS. 4a and 4b show pillars at the smaller pitch P₃, along line Z-Z′ of FIG. 4c. Pitch P₃, measured in the direction perpendicular to data lines 200, should be about the same as the pitch of data lines 200 (preferably between about 180 and 360 nm), so that each pillar 300 is on top of one of the data lines 200. Some misalignment can be tolerated. Pitch P₄, measured parallel to data lines 200, should be larger than pitch P₃, preferably about 1.5 times P₃, though if desired it may be larger or smaller.

To summarize, pillars 300 are formed by a method comprising depositing a semiconductor layer stack above a substantially planar surface coexposing the first data lines 200 separated by dielectric fill 108; and patterning and etching the semiconductor layer stack to form first pillars 300, each pillar 300 above one of the first data lines 200.

Turning to FIG. 4d, a thin gate dielectric layer 126 is conformally deposited over pillars 300, surrounding and in contact with each pillar 300. Gate dielectric layer 126 can be any appropriate material, for example silicon dioxide, and may have any appropriate thickness, for example between about 20 and about 80 angstroms, preferably about 50 angstroms.

Next a gate material layer 128 is deposited over gate dielectric layer 126, over and between first pillars 300. Gate material layer 128 is preferably tantalum nitride, though any other suitable conductive material, for example heavily doped silicon or a metal, can be used instead.

FIG. 4e shows the structure of FIG. 4d viewed at 90 degrees, along line W-W′ of FIG. 4c. The thickness of tantalum nitride layer 128 is selected so that the sidewalls merge in one direction (having smaller pitch P₃) but not in the other direction (having larger pitch P₄). For example, suppose pitch P₃ is 180 nm and pitch P₄ is 270 nm. Suppose further that the width of pillars 300 is about 90 nm, and the gap between them, in the direction of smaller pitch P₃, is about 90 nm; thus the gap between pillars 300 in the P₄ pitch direction is 180 nm. A thickness of about 45 nm of tantalum nitride layer 128 will just fill gaps in the P₃ pitch direction (shown in FIG. 4d), and will leave a gap G of 90 nm in the P₄ pitch direction (shown in FIG. 4e.) Preferably the thickness of tantalum nitride layer 128 is between one-half the width of pillars 300 and about three-quarters the width of pillars 300. Thus if pillars 300 have a width of about 90 nm, the preferred thickness of tantalum nitride layer 128 is between about 45 nm and about 72 nm, preferably about 60 nm. A thickness of 60 nm will leave a gap of about 60 nm in the P₄ pitch direction.

Turning to FIG. 4f, which shows the structure in the P₃ pitch direction, and FIG. 4g, which shows the structure in the P₄ pitch direction, an etch is performed to recess tantalum nitride layer 128 and to isolate select lines 130. Select lines 130 consist of merged tantalum nitride layer 128 in the P₃ pitch direction (FIG. 4f), but should be fully separate in the P₄ pitch direction (FIG. 4g). Select lines 130 are substantially parallel and substantially coplanar.

This etch should be a timed etch, and should be carefully controlled. After the etch, tantalum nitride layer 128 is preferably at least 50 nm below the top of conductive layer 123. This 50 nm gap will be filled with dielectric, and will serve to isolate select lines 130 from overlying conductors yet to be formed. Tantalum nitride layer 128 should not be etched so far, however, that it fails to reach the lower edge of heavily doped region 116, which will be the source/drain region of the transistor.

Next, turning to FIGS. 4h and 4i, dielectric material 108 is deposited over and between pillars 300 and tantalum nitride layer 128, filling the gaps between them. Dielectric material 108 can be any known electrically insulating material, such as silicon oxide, silicon nitride, or silicon oxynitride. In a preferred embodiment, silicon dioxide is used as the insulating material. The silicon dioxide can be deposited using any known process, such as CVD or HDPCVD.

Next the dielectric material on top of the pillars 300 is removed, exposing conductive layer 123 separated by dielectric material 108. Gate dielectric layer 126 is removed from above conductive layer 123 at the same time. This removal of dielectric overfill and planarization can be performed by any process known in the art, such as CMP or etchback.

Substantially parallel, substantially coplanar reference line 400 can be formed by any suitable method. Reference lines 400 can be formed using the methods used to form data lines 200: Deposit titanium nitride layer 132, deposit aluminum layer 134, deposit titanium nitride layer 136, then pattern and etch to form reference lines 400. A dielectric material 108 is deposited over and between reference lines 400. Alternatively, reference lines 400 can be formed by a damascene method. Reference lines 400 preferably have about the same width as data lines 200. The pitch of reference lines should be pitch P₄, so that each pillar 300 is vertically disposed between one of the data lines 200 and one of the reference lines 400. Some misalignment can be tolerated.

Alternatively, reference lines 400 can be formed by a damascene method, for example comprising copper. If reference lines 400 are formed by a damascene method, they will be formed by depositing a dielectric material; etching substantially parallel trenches in the dielectric material; depositing a conductive material on the dielectric material, filling the trenches; and planarizing to expose the dielectric material and form the reference lines 400.

FIG. 4j shows the structure viewed from above. The view of FIG. 4h is along line Z-Z′, and the view of FIG. 4i is along line W-W′.

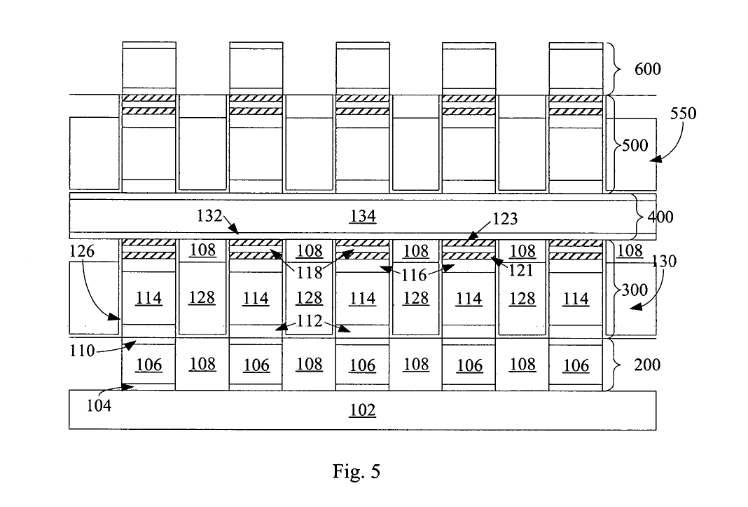

What has been formed in FIGS. 4h and 4i is a first memory level. In each memory cell, tantalum nitride layer 128 serves as a gate electrode. When threshold voltage is applied to gate electrode 128, a vertical conductive channel is formed at the surface of channel region 116, and current may flow between source/drain regions 114 and 118. In this example the gate electrode 128 does not comprise doped semiconductor material. Each gate electrode is a portion of one of the select lines 130. NiO layer 118 serves as a resistance-switching element. Additional memory levels can be formed above this memory level, using the methods described. For example, turning to FIG. 5, after a planarizing step exposes the tops of reference lines 400, second pillars 500, surrounded by gate electrode material merging to form second select lines 550, can be formed on reference lines 400, and second data lines 600 can be formed above second pillars 500. FIG. 5 shows two memory levels sharing reference lines 400.

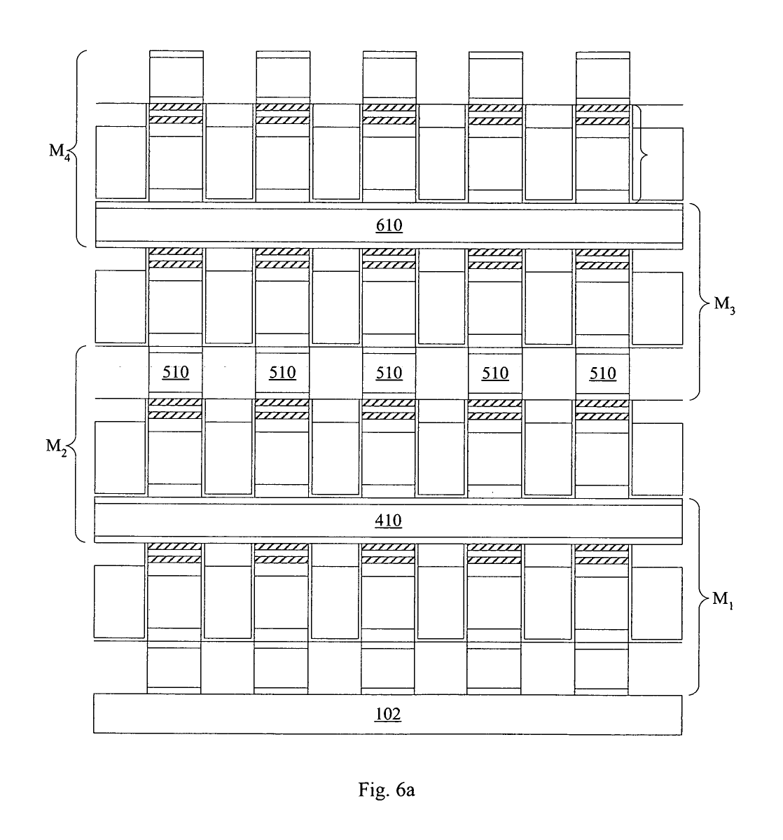

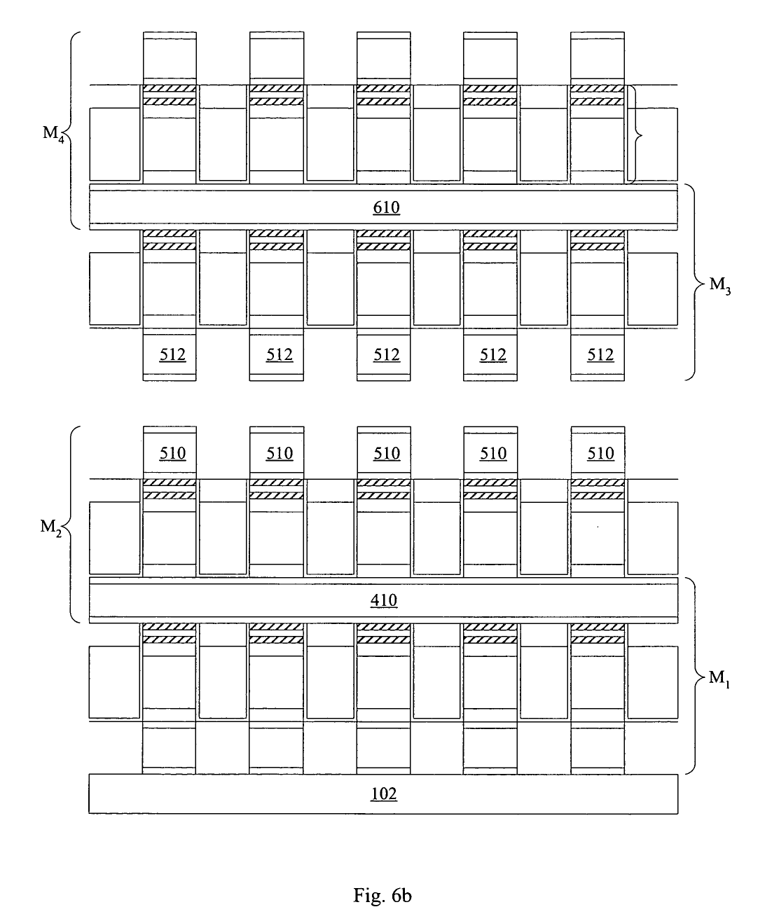

Additional memory levels can be formed above the first two memory levels pictured in FIG. 5. Data lines can be shared as well, or they can be separate. FIG. 6a shows four memory levels: Memory levels M₁ and M₂ share reference lines 410, memory levels M₂ and M₃ share data lines 510, and memory levels M₃ and M₄ share reference lines 610. FIG. 6b shows four memory levels in which reference lines (410 and 61) are shared, but data lines (510 and 512) are not shared between the memory levels M₂ and M₃. The arrangement of FIG. 6a requires fewer masking steps, and may be preferable for that reason.

In most preferred embodiments, control circuitry is formed in the substrate beneath the memory, and electrical connections must be made from the ends of the data lines, reference lines, and select lines of the array to this circuitry. An advantageous scheme for making these connections while minimizing use of substrate area is described in Scheuerlein et al., U.S. Pat. No. 6,879,505, “Word line arrangement having multi-layer word line segments for three-dimensional memory array,” owned by the assignee of the present invention and hereby incorporated by reference. The arrangement of FIG. 6b, while requiring more masking steps, can make use of the techniques described by Scheuerlein et al., and my be preferred for that reason.

The structures and processes described in this example can be modified in many ways, yet fall within the scope of the invention. For example, referring to FIGS. 4h and 4i, during formation of the first memory level, conductive layer 121, NiO layer 118 and conductive layer 123 could be deposited before, rather than after, germanium layers 112, 114, and 116. These layers could be etched into pillars in a single patterning step as described. Alternatively, layers 123, 118, and 121 could be etched in a separate etch step, and the gaps between them filled. A planarizing step would create a planar surface and expose conductive layer 123, and deposition of germanium would begin.

In yet another alternative fabrication process, germanium that will make up layers 112, 114, and 116 could be deposited, doped, patterned and etched into diodes, then gate dielectric layer 126 and gate material layer 128 deposited. Gate material layer 128 is then etched back to expose the top of the germanium pillar and recess select lines 130. Next dielectric material 108 is deposited over and between select lines 130, filling gaps between them, and a planarizing step exposes the tops of the germanium pillars and forms a planar surface. In preferred embodiments, the ion implantation step to form heavily doped region 116 is performed after this planarizing step. Next conductive layer 121, NiO layer 118 and conductive layer 123 are deposited on the planar surface, then etched to form short pillars, each ideally having the same size and centered on one of the germanium pillars, though some misalignment can be tolerated. Gaps between the pillars consisting of layers 121, 118, and 123 are then filled with dielectric, and a second planarizing step exposes layer 123. Top conductors are formed as described above.

Other methods of fabrication can be imagined. The number of masking steps could be minimized by patterning pillars 300 and 500 of FIG. 5 in self-aligned patterning steps with the data lines and reference lines above and below. A related method is described in Lee et al., specifically in the embodiment described in FIGS. 13 through 28.

Vertical Transistor Embodiment: Programming and Sensing

A cell formed according to the embodiment just described is programmed or erased by converting the resistance-switching material of that cell from a low-resistance state to a high-resistance state or vice versa. For simplicity a voltage applied to convert resistance-switching material from a high-resistance state to a low-resistance state will be called the set voltage, while a voltage applied to convert resistance-switching material from a high-resistance state to a low-resistance state will be called the reset voltage.

Resistance-switching memory elements formed of resistance-switching material will have different switching voltages depending on the material selected, the thickness of the material, deposition conditions, whether or not it is formed sandwiched between noble metal layers, and many other factors. Suppose, for a given resistance-switching memory element, the set voltage is about 1.0 volts, while the reset voltage is about 0.5 volts. For clarity, voltages will be provided in this discussion. It will be understood, however, that, depending on materials selected, dimensions of the memory cells, layer thicknesses, dopant levels, and many other factors, different voltages may be preferred.

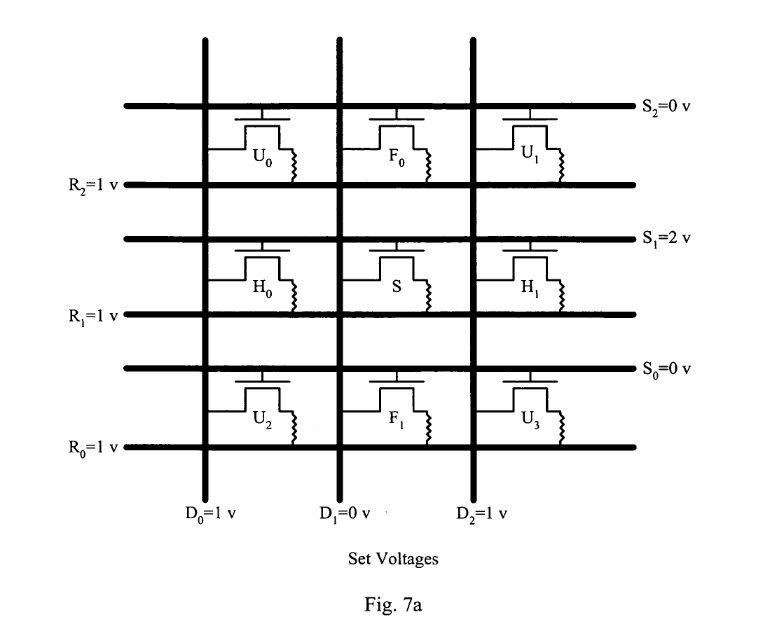

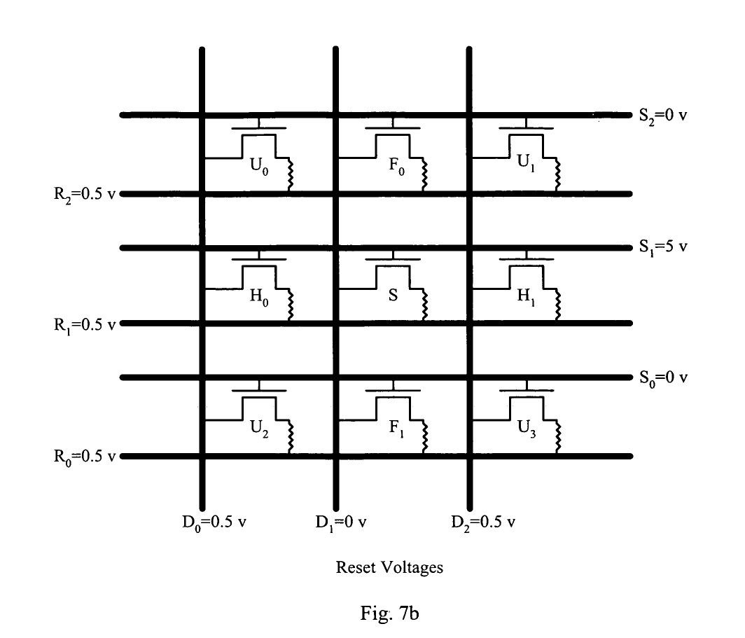

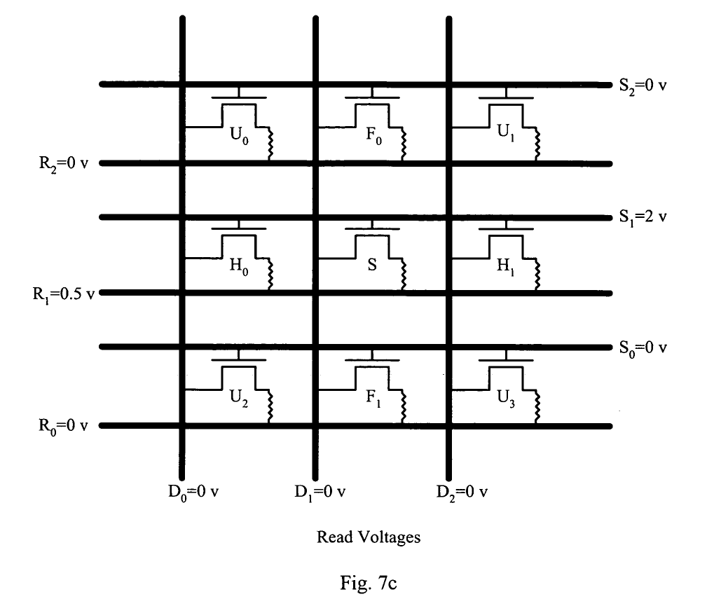

FIG. 7a is a circuit diagram in which data lines D₀, D₁, and D₂ correspond to any three adjacent data lines 200 in FIG. 4h. S₀, S₁, and S₂ correspond to any three adjacent select lines 130, while R₀, R₁, and R₂ correspond to any three adjacent reference lines 400 in FIG. 4h. To program selected cell S (to convert it to the set, or low-resistance, state), which is accessed by data line D₁, select line S₁, and reference line R₁, a voltage above the threshold voltage and above the set voltage, for example about 2 volts, is applied to select line S₁, forming a conductive channel in the channel region of cell S. Data line D₁ is set to ground, while the set voltage of 1 volt is applied to reference line R₁. The set voltage is thus applied across the resistance-switching memory element (which is in series with the transistor of cell S) and the resistance-switching memory material is converted from the high-resistance to the low-resistance state.

Inadvertent resistance conversion of other cells in the array should be avoided, however. A gate voltage above threshold voltage is applied to cells H₀ and H₁, which share select line S₁ and reference line R₁ with selected cell S. Data lines D₀ of cell H₀ and D₂ of cell H₂ are set to 1 volt. There is no voltage drop between reference line R₁ and data line D₀ of cell H₀ or between reference line R₁ and data line D₂ of cell H₂, so no voltage is applied across the resistance-switching material of cells H₀ or H₁, and neither is disturbed. Cells F₀ and F₁, share data line D₁ with selected call S. To avoid inadvertent resistance conversion of cells F₀ and F₁, unselected select lines S₀ and S₂ (and all other unselected select lines in the array) are set to ground. No gate voltage is applied to these transistors, so they are not turned on.

Cells U₀, U₁, U₂, and U₃ share no select line, data line or reference line with selected cell S. Their select lines S₀ and S₂ are at ground, so no gate voltage is applied to these unselected cells. Setting reference lines R₀ and R₂ and data lines D₀ and D₂ to 1 volt minimizes leakage current across these cells. Alternatively, unselected reference lines R₀ and R₂ could be set to ground.

FIG. 7b illustrates biases to apply a reset voltage of 0.5 volts to selected cell S. Select line S₁ is set at 5 volts, providing adequate gate voltage to turn on transistor S, while applying 0.5 volts (the reset voltage) to reference line R₁ and setting data line D₁ to ground causes switching of the resistance-switching memory element of cell S from the low-resistance to the high-resistance state.

To avoid inadvertent resistance switching of cells H₀ and H₁, which share select line S₁ and reference line R₁ with selected cell S, data lines D₀ and D₂ are set to 0.5 volts, so while these transistors are above threshold voltage, there is no voltage drop across their channels. Unselected select lines S₀ and S₂ are set to ground, so that cell F₀, F₁, and U₀-U₃ have no applied gate voltage. Leakage current across unselected cells U₀-U₃ is minimized by setting unselected reference lines R₀ and R₂ to 0.5 volts, though these could be set to ground.

FIG. 7c shows read of cell S. Select line S₁ is set to 2 volts. Data line D₁ is set to ground, while reference line R1 is set to a read voltage of 0.5 volts. If the resistance-switching memory element of cell S is in the low-resistance state, measurably more current will flow than if the resistance-switching memory element of cell S is in the high-resistance state. Unselected select lines S₀ and S₂ are set to ground, as are unselected data lines D₀ and D₂ and unselected reference lines R₀ and R₂.

Lateral Transistor Embodiment: Fabrication

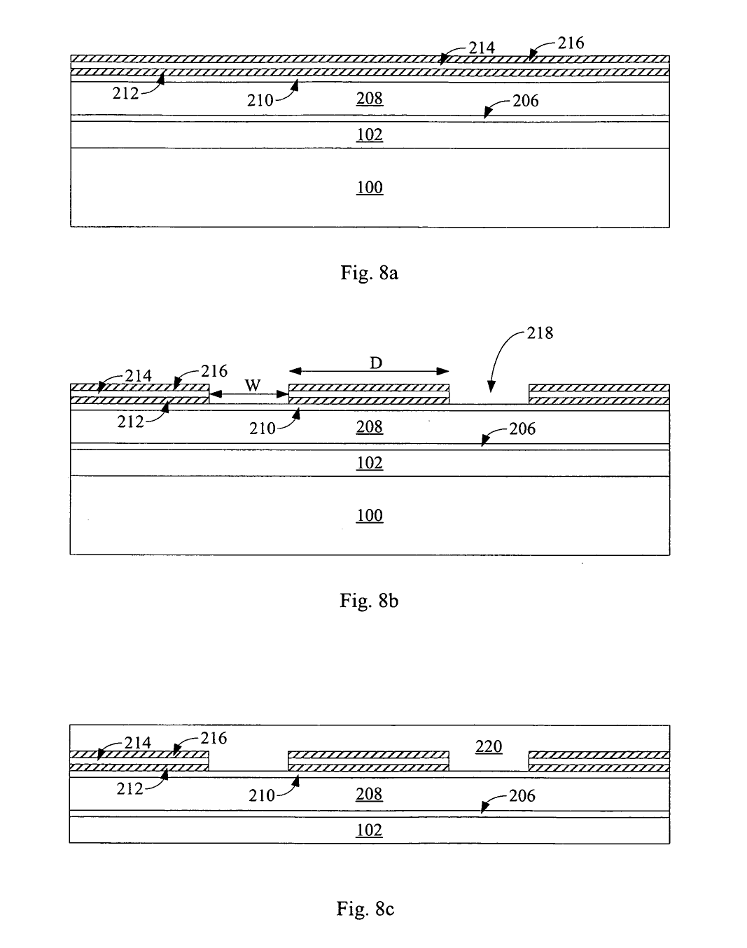

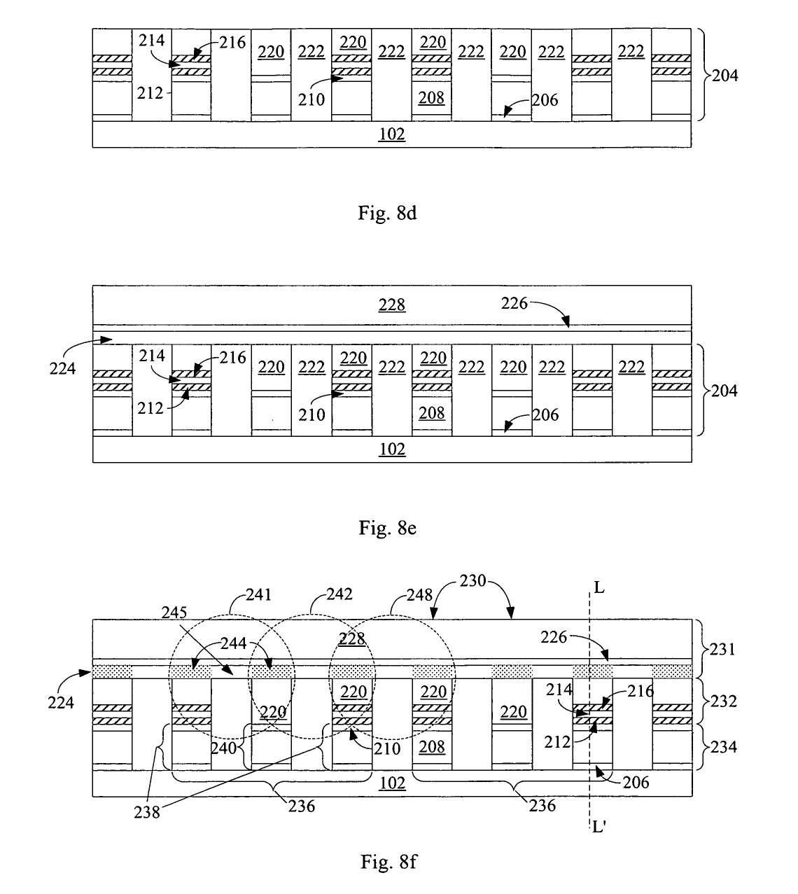

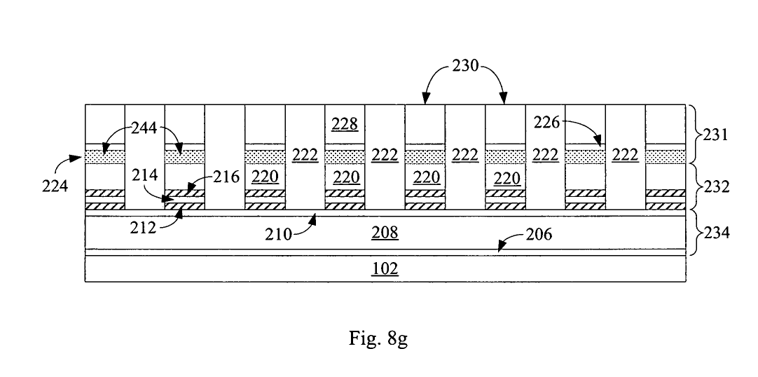

Turning to FIG. 8a, as in the prior embodiment, fabrication begins over a suitable substrate 100 and insulating layer 102. As described earlier, substrate 100 may include integrated circuits fabricated therein.

Optionally an adhesion layer 206 of, for example, titanium nitride is deposited on insulating layer 102. Conductive layer 208, which may be formed of tungsten, aluminum or an aluminum alloy, heavily doped semiconductor material, or some other suitable material, is deposited next. Layer 208 can be any appropriate thickness, for example about 150 nm. Barrier layer 210 is deposited next; this layer is preferably between about 10 and about 40 nm, most preferably about 20 nm or less.

Next a layer 212 of a conductive material, for example a noble metal such as Ir, Pt, Pd or Au, is deposited. The thickness of layer 212 may be between about 10 and about 40 nm, preferably about 20 nm. In some embodiments, layer 212 may be omitted, or some other conductive material can be used instead. A layer 214 of a binary metal oxide or nitride resistance-switching material is deposited on conductive layer 212. This layer is preferably between about 20 and about 40 nm thick. Layer 214 can be any of the materials described earlier, and is preferably formed of a binary metal oxide or nitride having including exactly one metal which exhibits resistance switching behavior; preferably a material selected from the group consisting of NiO, Nb₂O₅, TiO₂, HfO₂, Al₂O₃, MgOₓ, CrO₂, VO, BN, and AlN. For simplicity this discussion will describe the use of NiO in layer 214. It will be understood, however, that any of the other materials described can be used.

Finally in preferred embodiments conductive layer 216 is deposited on NiO layer 214. Layer 216 is preferably a noble metal such as Ir, Pt, Pd or Au, though some other appropriate conductive barrier material may be used instead. In some embodiments, layer 216 may be omitted.

Turning to FIG. 8b, a pattern and etch step is performed to etch slots 218 through conductive layer 216, NiO layer 214, and, optionally, through conductive layer 212. The width W of slots 218 is narrower than the distance D between them, preferably half distance D. For example, width W can be between about 90 and 200 nm, preferably about 180 nm, while distance D is between about 180 nm and about 400 nm, preferably about 360 nm.

Turning to FIG. 8c, next heavily doped semiconductor material 220, preferably n-type silicon, germanium, or a silicon-germanium alloy, is deposited. Layer 220 is preferably about 90 nm thick. (In this and subsequent figures, substrate 100 has been omitted. Its presence will be assumed.)

Turning to FIG. 8d, a pattern and etch step is performed to etch the layers so far deposited into substantially parallel lines 204, which extend out of the page. The pitch of lines 204 should be about the same as the width W of the slots 218 formed in the etch step illustrated in FIG. 8b, for example between about 45 and about 100 nm, preferably about 90 nm. Ideally every third line 204 is centered in one of slots 218, though misalignment can be tolerated. In this way, every third line 204 does not include any portion of conductive layer 216 or NiO layer 214 (or of conductive layer 212, if it was etched in the etch step that formed slots 218.)

Next a dielectric material 222 is deposited over and between lines 204, filling gaps between them. A planarizing step is performed, for example by CMP or etchback, to form a substantially planar surface coexposing tops of lines 204 separated by dielectric material 222.

Turning to FIG. 8e, a channel layer 224 of a lightly doped or intrinsic semiconductor material, preferably p-type silicon, germanium, or a silicon-germanium alloy, is deposited on the substantially planar surface formed by the prior planarization step. This layer is preferably between about 60 and about 120 nm thick. Channel layer 224 layer may be amorphous as deposited, but in preferred embodiments will be polycrystalline in the completed device. A thin gate dielectric 226 is formed next, preferably by depositing between about 5 and 10 nm of, for example, silicon dioxide. Next a layer of conductive material 228 is deposited. This layer can be, for example heavily doped n-type silicon, germanium, or a silicon-germanium alloy, or some other suitable conductive material, such as a metal or conductive metal compound, for example tantalum nitride.

Turning to FIG. 8f, next a pattern and etch step is performed, etching conductive layer 228, gate dielectric layer 226, and channel layer 224, forming select lines 230 (which are coextensive with etched gate dielectric layer 226 and channel layer 224 in second rails 231.) The etch continues through semiconductor layer 220, conductive layer 216, NiO layer 214, and, optionally, conductive layer 212, forming pillars 232. FIG. 8g shows the structure of FIG. 8f viewed at 90 degrees along line L-L′,

This etch has also made pillars 232 distinct from first rails 234. In this example, first rails 234 include adhesion layer 206, conductive layer 208, and barrier layer 210. Returning to FIG. 8f, first rails 234 include line sets 236, each line set 236 consisting of two data lines 238 and one reference line 240, reference line 240 immediately adjacent to and between the two data lines 238. Each pillar 232 is vertically disposed between one of the first rails 234 and one of second rails 231.

Field effect transistors, for example 241 and 242, have been formed. Each is in electrical contact with a data line 238 and a reference line 236. During subsequent thermal processing, dopant diffuses upward from heavily doped semiconductor layer 220 into channel layer 224, forming heavily doped source/drain regions 244, leaving lightly doped channel regions 245 between them. Each transistor includes resistance-switching NiO layer 214 in one pillar 232, but not the other. The resistance-switching element 214 is disposed in a circuit path between the channel region 245 of its transistor and a reference line 236. In an alternative embodiment, the resistance-switching element can be disposed in a circuit path between the channel region of its transistor and a data line. The parasitic transistor formed at location 248, between adjacent data lines, is unused.

When transistor 241 is programmed, erased, and read, one of the data lines 238 acts as a source line to the field effect transistor 241, the immediately adjacent reference line 246 acts as a drain line to the field effect transistor, and the select line 230 acts as a gate electrode.

In some embodiments, for example at small feature size, the etch that forms top rails 231 and pillars 232, and following gap fill, may prove difficult. An alternative fabrication technique may be preferred. After the etch step that forms lines 204 (see FIG. 8d), an orthogonal pattern and etch step can be performed, etching semiconductor layer 220, conductive layer 216, NiO layer 214, and, optionally, conductive layer 212, forming pillars 232. Dielectric fill is then deposited between pillars 232, and a planarization step (by CMP or etchback) exposes tops of pillars 232. Next channel layer 224, gate dielectric 226, and conductive layer 228 are formed as before, and patterned and etched to form top rails 231. This technique requires extra processing steps, but in some embodiments may be preferred.

Dielectric fill 222 is deposited between top rails 231, and an interlevel dielectric is formed. A first memory level, pictured in FIGS. 8f and 8g, has been formed. Additional memory levels can be stacked above this first memory level, fabrication beginning on the interlevel dielectric and proceeding as described, to form a monolithic three dimensional memory array.

To summarize, an array formed according to the embodiment just described comprises a) a first plurality of substantially parallel, substantially coplanar rails extending in a first direction, wherein some of the first rails are first data lines and others of the first rails are first reference lines; b) a first plurality of substantially parallel, substantially coplanar select lines above the first rails extending in a second direction different from the first direction; c) a first plurality of pillars, each pillar disposed between one of the first rails and one of the first select lines; and d) a plurality of first memory cells, wherein each first memory cell comprises: one of the first pillars comprising a reversible resistance-switching memory element; one of the first pillars not comprising a reversible resistance-switching memory element; and a semiconductor channel region.

Lateral Transistor Embodiment: Programming and Sensing

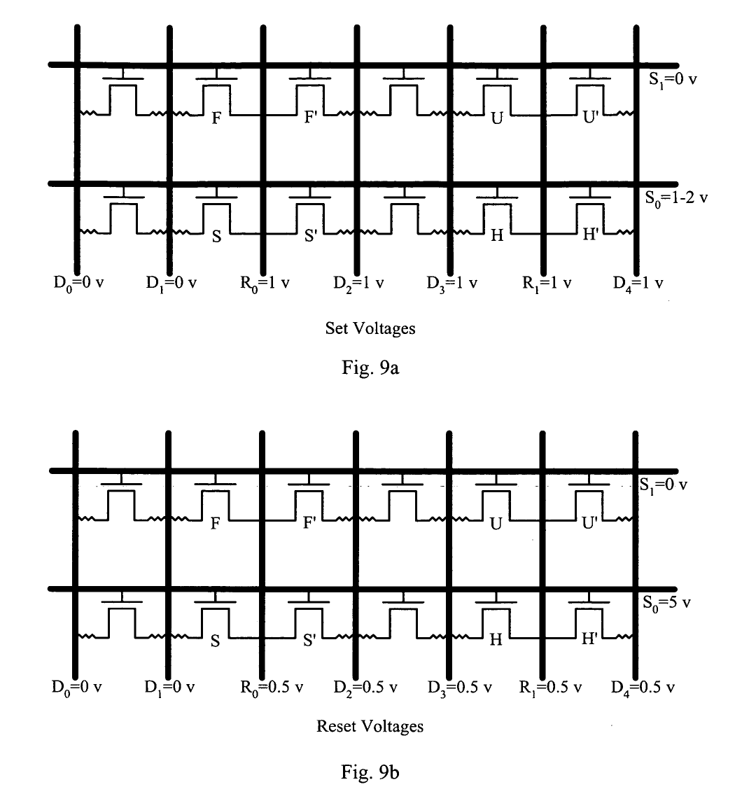

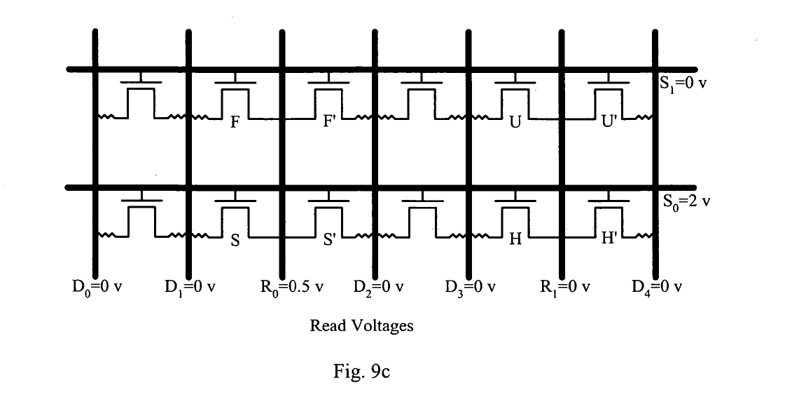

FIG. 9a illustrates how to apply set voltage to induce the high-resistance to low-resistance transition in selected cell S in a memory array like that pictured in FIGS. 8f and 8g.

Data line D₁, reference line R₀, and data line D₂ make up a first line set. Referring to FIG. 8f, these correspond to one of line sets 236, each of which includes two data lines 238 and reference line 240. Select line S₀ corresponds to select line 230.

To apply the set voltage to the resistance-switching memory element of selected cell S, the transistor is turned on by applying at least 1-2 volts to select line S₀. Data line D₁ is set to ground, while reference line R₀ is set to the set voltage, 1 volt in this example. To avoid disturb of adjacent cell S′, data line D₂ is set to 1 volt, so there is no voltage drop between reference line R₀ and data line D₂.

To avoid switching other cells in the array (cells F and F′, which share data lines and reference line with selected cell S and adjacent cell S′; cells H and H′, which share select line S₀ with selected cell S and adjacent cell S′, and cells U and U′, which share no lines with selected cell S and adjacent cell S′) unselected select line S₁ is set to ground. In adjacent line sets, unselected data lines D₃ and D₄ and reference line R₁ are set to 1 volt. Unshown additional data and reference lines to the right of data line D₄ in FIG. 9a are set to 1 volt. Unselected data line D₀ is set to ground, as are unshown additional data and reference lines to the left of data line D₀ in FIG. 9a.

Turning to FIG. 9b, cell S is reset by applying high voltage, for example 5 volts, to select line S₀. Data line D₁ is set to ground, while reference line R₀ is set to the reset voltage, 0.5 volts. Data line D₂ is also set to 0.5 volts to avoid resetting adjacent cell S′. To avoid inadvertent reset of other cells, unselected select line S₁ is set to ground. Unselected data lines D₃ and D₄ and unselected reference line R₁ are set to 0.5 volts, along with additional data lines and reference lines to the right of data line D₄ in FIG. 9b, are set to 0.5 volts. Data line D₀, and additional data lines and reference lines to the left of data line D₀ in FIG. 9b, are set to ground.

FIG. 9c illustrates reading selected cell S. Select line S₀ is set to 2 volts, while data line D₁ is set to ground and reference line R₀ is set to 0.5 volts. Unselected select line S₁ is set to ground. Unselected data lines D₂, D₃, and D₄ can be set to 0.5 volts, as are additional unselected data and reference lines to the right of data line D₃ is FIG. 9c. Preferably unselected data line D₀ is set to ground, as are additional unselected data lines and reference lines to the left of data line D₀ is FIG. 9c.

Embodiments of the present invention provide for a monolithic three dimensional memory array comprising: a) a first memory level formed above a substrate, the first memory level comprising a first plurality of memory cells, each first memory cell comprising: i) a transistor; and ii) a reversible resistance-switching element, wherein resistance switching is not achieved through phase change, the transistor and the resistance-switching element arranged in series; and b) a second memory level monolithically formed above the first memory level.

A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167, “Three dimensional structure memory.” The substrates may be thinned or removed from the memory levels before bonding, but as the memory levels are initially formed over separate substrates, such memories are not true monolithic three dimensional memory arrays.

A monolithic three dimensional memory array formed above a substrate comprises at least a first memory level formed at a first height above the substrate and a second memory level formed at a second height different from the first height. Three, four, eight, or indeed any number of memory levels can be formed above the substrate in such a multilevel array.

Detailed methods of fabrication have been described herein, but any other methods that form the same structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed is:

1. A nonvolatile memory cell comprising:
a reversible resistance-switching binary metal oxide or nitride element; and
a transistor, the resistance-switching element and the transistor arranged in series.

2. The nonvolatile memory cell of claim 1 wherein the resistance-switching element comprises a material selected from the group consisting of NiO, Nb₂O₅, TiO₂, HfO₂, Al₂O₃, MgOₓ, CrO₂, VO, BN, and AlN.

3. The nonvolatile memory cell of claim 1 wherein the transistor is a field effect transistor further comprising a gate electrode.

4. The nonvolatile memory cell of claim 3 wherein the transistor comprises a channel region, the channel region comprising polycrystalline, amorphous, or microcrystalline semiconductor material.

5. The nonvolatile memory cell of claim 4 wherein the semiconductor material is silicon, germanium, or a silicon-germanium alloy.

6. The nonvolatile memory cell of claim 4 further comprising a vertically oriented semiconductor pillar, wherein the pillar comprises the channel region.

7. The nonvolatile memory cell of claim 6 wherein the gate electrode does not comprise doped semiconductor material.

8. The nonvolatile memory cell of claim 6 wherein the resistance-switching element is above the semiconductor pillar.

9. The nonvolatile memory cell of claim 6 wherein the resistance-switching element is below the semiconductor pillar.

10. The nonvolatile memory cell of claim 6 wherein the semiconductor pillar comprises a bottom heavily doped region of a first conductivity type, a middle intrinsic or lightly doped region of a second conductivity type, and a top heavily doped region of the first conductivity type.

11. The nonvolatile memory cell of claim 6 wherein the semiconductor pillar is disposed between a data line and a reference line.

12. The nonvolatile memory cell of claim 11 wherein neither the data line nor the reference line comprises monocrystalline silicon.

13. The nonvolatile memory cell of claim 5 wherein the transistor comprises a substantially horizontal channel region.

14. The nonvolatile memory cell of claim 13 wherein the transistor is in electrical contact with a data line and a reference line.

15. The nonvolatile memory cell of claim 14 wherein the resistance-switching element is disposed in a circuit path between the channel region and the data line.

16. A nonvolatile memory cell comprising:
a reversible resistance-switching element, wherein resistance switching is not achieved through phase change; and
a thin film transistor having a deposited semiconductor channel region,
wherein the thin film transistor and the resistance-switching element are arranged in series.

17. The nonvolatile memory cell of claim 16 wherein the reversible resistance-switching element comprises a binary metal oxide or nitride.

18. The nonvolatile memory cell of claim 17 wherein the binary metal oxide or nitride is selected from the group consisting of NiO, Nb₂O₅, TiO₂, HfO₂, Al₂O₃, MgOₓ, CrO₂, VO, BN, and AlN.

19. The nonvolatile memory cell of claim 17 wherein the binary metal oxide or nitride is above and in contact with a first conductive layer comprising a noble metal.

20. The nonvolatile memory cell of claim 19 wherein the binary metal oxide or nitride is below and in contact with a second conductive layer comprising a noble metal.

21. The nonvolatile memory cell of claim 16 wherein the semiconductor channel region is silicon, germanium, or a silicon-germanium alloy.

22. The nonvolatile memory cell of claim 16 wherein the thin film transistor comprises a vertically oriented semiconductor pillar, the pillar comprising the channel region.

23. The nonvolatile memory cell of claim 22 wherein the semiconductor pillar comprises a bottom heavily doped region of a first conductivity type, a middle intrinsic or lightly doped region of a second conductivity type, and a top heavily doped region of the first conductivity type.

24. The nonvolatile memory cell of claim 22 wherein the resistance-switching element is disposed above the semiconductor pillar.

25. The nonvolatile memory cell of claim 22 wherein the. resistance-switching element is disposed below the semiconductor pillar.

26. The nonvolatile memory cell of claim 22 wherein the semiconductor pillar is vertically disposed between a data line and a reference line.

27. The nonvolatile memory cell of claim 16 wherein the thin film transistor comprises a substantially horizontally oriented channel region.

28. The nonvolatile memory cell of claim 27 wherein the resistance-switching element is disposed in a circuit path between the channel region and a data line.

29. The nonvolatile memory cell of claim 28 wherein the data line does not comprise monocrystalline semiconductor material.

30. A nonvolatile memory cell comprising:
a vertically oriented transistor having a polycrystalline channel region; and
a reversible resistance-switching element, wherein resistance switching is not achieved through phase change,
wherein the resistance-switching element is electrically in series with the vertically oriented transistor.

31. The nonvolatile memory cell of claim 30 wherein the reversible resistance-switching element comprises a binary metal oxide or nitride.

32. The nonvolatile memory cell of claim 31 wherein the binary metal oxide or nitride is selected from the group consisting of NiO, Nb₂O₅, TiO₂, HfO₂, Al₂O₃, MgOₓ, CrO₂, VO, BN, and AlN.

33. The nonvolatile memory cell of claim 30 wherein the polycrystalline channel region comprises silicon, germanium, or a silicon-germanium alloy.

34. The nonvolatile memory cell of claim 30 wherein the transistor and the resistance-switching element are vertically disposed between a data line and a reference line.

35. The nonvolatile memory cell of claim 34 wherein the resistance-switching element is disposed between the transistor and the data line.

36. The nonvolatile memory cell of claim 34 wherein the resistance-switching element is disposed between the transistor and the reference line.

37. The nonvolatile memory cell of claim 34 wherein neither the data line nor the reference line comprises monocrystalline silicon.

38. The nonvolatile memory cell of claim 34 wherein the data line or the reference line comprises aluminum or copper.

39. The nonvolatile memory cell of claim.30 wherein the vertically oriented transistor comprises a bottom heavily doped region of a first conductivity type, an intrinsic or lightly doped middle region of a second conductivity type, and a top heavily doped region of the first conductivity type.

40. The nonvolatile memory cell of claim 30 wherein the transistor further comprises a gate electrode not comprising semiconductor material.

41. A monolithic three dimensional memory array comprising:
a) a first memory level formed above a substrate, the first memory level comprising a first plurality of memory cells, each first memory cell comprising:
i) a transistor; and
ii) a reversible resistance-switching element, wherein resistance switching is not achieved through phase change, the transistor and the resistance-switching element arranged in series; and
b) a second memory level monolithically formed above the first memory level.

42. The monolithic three dimensional memory array of claim 41 wherein the resistance-switching element of each first memory cell comprises a binary metal oxide or nitride.

43. The monolithic three dimensional memory array of claim 42 wherein the binary metal oxide or nitride is selected from the group consisting of NiO, Nb₂O₅, TiO₂, HfO₂, Al₂O₃, MgOₓ, CrO₂, VO, BN, and AlN.

44. The monolithic three dimensional memory array of claim 42 wherein the binary metal oxide or nitride is disposed above and contacting a noble metal layer.

45. The monolithic three dimensional memory array of claim 44 wherein the binary metal oxide or nitride is disposed below and contacting a noble metal layer.

46. The monolithic three dimensional memory array of claim 41 wherein the transistor comprises a channel region, the channel region comprising silicon, germanium, or a silicon-germanium alloy.

47. The monolithic three dimensional memory array of claim 46 wherein the channel region is substantially vertical.

48. The monolithic three dimensional memory array of claim 47 wherein the channel region of each first transistor is disposed in a vertically oriented semiconductor pillar.

49. The monolithic three dimensional memory array of claim 48 wherein the first memory level further comprises a first plurality of substantially parallel, substantially coplanar data lines.

50. The monolithic three dimensional memory array of claim 49 wherein the first memory level further comprises a first plurality of substantially parallel, substantially coplanar reference lines, each first transistor disposed between one of the first data lines and one of the first reference lines.

51. The monolithic three dimensional memory array of claim 47 wherein each first memory cell further comprises a gate electrode.

52. The monolithic three dimensional memory array of claim 50 wherein the first memory level further comprises a first plurality of substantially parallel, substantially coplanar select lines.

53. The monolithic three dimensional memory array of claim 52 wherein the gate electrode of each first memory cell is a portion of one of the first select lines.

54. The monolithic three dimensional memory array of claim 41 wherein the substrate comprises monocrystalline silicon.

55. The monolithic three dimensional memory array of claim 41 wherein the second memory level comprises a second plurality of memory cells, each second memory cell comprising:
a transistor; and
a reversible resistance-switching element, the transistor and the resistance-switching element arranged in series.

56. A method for forming a monolithic three dimensional memory array, the method comprising:
forming a first plurality of substantially parallel, substantially coplanar data lines above a substrate;
forming a first plurality of vertically oriented transistors above the first data lines;
forming a first plurality of reversible resistance-switching elements; and
forming a first plurality of substantially parallel, substantially coplanar reference lines above the first transistors,
wherein one of the first resistance-switching elements and one of the first transistors is arranged in series between each of the first data lines and each of the first reference lines.

57. The method of claim 56 wherein the step of forming the first data lines comprises:
depositing a first conductive material; and
patterning and etching the first conductive material to form the first data lines.

58. The method of claim 57 wherein the first conductive material is tungsten, aluminum, or an aluminum alloy.

59. The method of claim 56 wherein the step of forming the first vertically oriented transistors comprises:
depositing a semiconductor layer stack above a substantially planar surface coexposing the first data lines separated by dielectric fill; and
patterning and etching the semiconductor layer stack to form first pillars, each pillar above one of the first data lines.

60. The method of claim 59 wherein the semiconductor layer stack comprises semiconductor material, wherein the semiconductor material is silicon, germanium, or a silicon-germanium alloy.

61. The method of claim 59 wherein the step of forming the first vertically oriented transistors further comprises:
forming a gate dielectric surrounding and in contact with each of the first pillars; and
depositing a gate electrode material over and between the first pillars.

62. The method of claim 56 wherein the step of forming the first reference lines comprises:
depositing a second conductive material; and
patterning and etching the second conductive material to form the first reference lines.

63. The method of claim 62 wherein the second conductive material comprises aluminum, an aluminum alloy, or tungsten.

64. The method of claim 56 wherein the step of forming the first reference lines comprises:
depositing a dielectric material;
etching substantially parallel trenches in the dielectric material;
depositing a second conductive material on the dielectric material, filling the trenches; and
planarizing to expose the dielectric material and form the reference lines.

65. The method of claim 64 wherein the second conductive material is copper.

66. The method of claim 56 wherein the step of forming the first reversible resistance switching elements comprises depositing a first reversible resistance-switching material, the resistance-switching material selected from the group consisting of NiO, Nb₂O₅, TiO₂, HfO₂, Al₂O₃, MgOₓ, CrO₂, VO, BN, and AlN.

67. The method of claim 56 further comprising forming a second plurality of substantially parallel, substantially coplanar data lines above the first reference lines.

68. The method of claim 67 further comprising forming a second plurality of vertically oriented transistors above the first reference lines.

69. A monolithic three dimensional memory array comprising:
a) a first plurality of substantially parallel, substantially coplanar rails extending in a first direction, wherein some of the first rails are first data lines and others of the first rails are first reference lines;
b) a first plurality of substantially parallel, substantially coplanar select lines above the first rails extending in a second direction different from the first direction;
c) a first plurality of pillars, each pillar disposed between one of the first rails and one of the first select lines; and
d) a plurality of first memory cells, wherein each first memory cell comprises:
one of the first pillars comprising a reversible resistance-switching memory element;
one of the first pillars not comprising a reversible resistance-switching memory element; and
a semiconductor channel region.

70. The monolithic three dimensional memory array of claim 69 wherein each semiconductor channel region is coextensive with one of the first select lines.

71. The monolithic three dimensional memory array of claim 60 wherein the semiconductor channel region comprises a deposited semiconductor material, wherein the semiconductor material is silicon, germanium, or a silicon-germanium alloy.

72. The monolithic three dimensional memory array of claim 71 wherein the semiconductor material is polycrystalline.

73. The monolithic three dimensional memory array of claim 69 wherein the first rails comprise a plurality of line sets, each line set consisting of two of the first data lines and one of the first reference lines, the first reference line immediately adjacent to and between the two first data lines.

74. The monolithic three dimensional memory array of claim 73 wherein each memory cell further comprises a field effect transistor, one of the data lines acting as a source line to the field effect transistor, the immediately adjacent reference line acting as a drain line to the field effect transistor, and one of the select lines acting as a gate electrode to the transistor.

75. The monolithic three dimensional memory array of claim 69 wherein each reversible resistance-switching element is formed of a resistance-switching material, the resistance-switching material selected from the group consisting of NiO, Nb₂O₅, TiO₂, HfO₂, Al₂O₃, MgOₓ, CrO₂, VO, BN, and AlN.

76. The monolithic three dimensional memory array of claim 69 wherein first data lines comprise tungsten, aluminum, or an aluminum alloy.

77. The monolithic three dimensional memory array of claim 69 further comprising a second plurality of substantially parallel, substantially coplanar rails, wherein some of the second rails are second data lines and others of the second rails are second reference lines, the second rails formed above the first select lines.
